(19) United States
(12) Patent Application Publication
(10) Pub. No.: US 2015/0034627 A1
(43) Pub. Date: Feb. 5, 2015

(54) CIRCUIT BOARD TEST APPARATUS WITH ELECTRIC HEATING MEMBER

(71) Applicant: HON HAI PRECISION INDUSTRY CO., LTD., New Taipei (TW)

(72) Inventors: CHIOU-CHUAN WU, New Taipei (TW); LI-MING LIOU, New Taipei (TW)

(73) Assignee: HON HAI PRECISION INDUSTRY CO., LTD., New Taipei (TW)

(21) Appl. No.: 13/968,441

(22) Filed: Aug. 16, 2013

(30) Foreign Application Priority Data
Aug. 1, 2013 (TW) 102127680

(51) Int. Cl. G01R 31/28; H05B 3/10

(52) U.S. Cl. CPC G01R 31/2863; H05B 3/10
USPC 219/540; 219/541

(57) ABSTRACT

An electric heating member includes a position plate, a connecting plate extending out from a first side of the position plate, a first cable, a second cable, and a number of electric heat tabs. The first cable includes a first conductive portion arranged on the first side of the position plate, and a first extension portion extending to the connecting plate for being electrically coupled to a power supply. The second cable includes a second conductive portion arranged on a second side of the position plate opposite to the first conductive portion, and a second extension portion extending to the connecting plate for being electrically coupled to the power supply. The electric heat tabs are set on the position plate and arrayed along a lengthwise direction of the position plate. The electric heat tabs are connected to the first conductive portion and the second conductive portion in parallel.

### BACKGROUND

1. Technical Field

The present disclosure relates to circuit board test apparatus, and particularly to a circuit board test apparatus with an electric heating member.

2. Description of Related Art

Thermal characteristic of the circuit board is one of the most important factors affecting reliability and stability of a computer system. Therefore, before manufacturing the computer systems, designers need to perform thermal characteristic tests on their designs of the circuit boards. However, usually, designers can only do the tests by direct test on samples of computer systems. However, manufacturing samples of the computer systems is costly and time consuming.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of an embodiment of a circuit board test apparatus, wherein the circuit board test apparatus includes an electric heating member.

FIG. 2 is an enlarged, isometric view of the electric heating member of FIG. 1.

FIG. 3 is an assembled, isometric view of the circuit board test apparatus of FIG. 1.

### DETAILED DESCRIPTION

The present disclosure, including the accompanying drawings, is illustrated by way of examples and not by way of limitation. It should be noted that references to “an” or “one” embodiment in this disclosure are not necessarily to the same embodiment, and such references mean “at least one.”

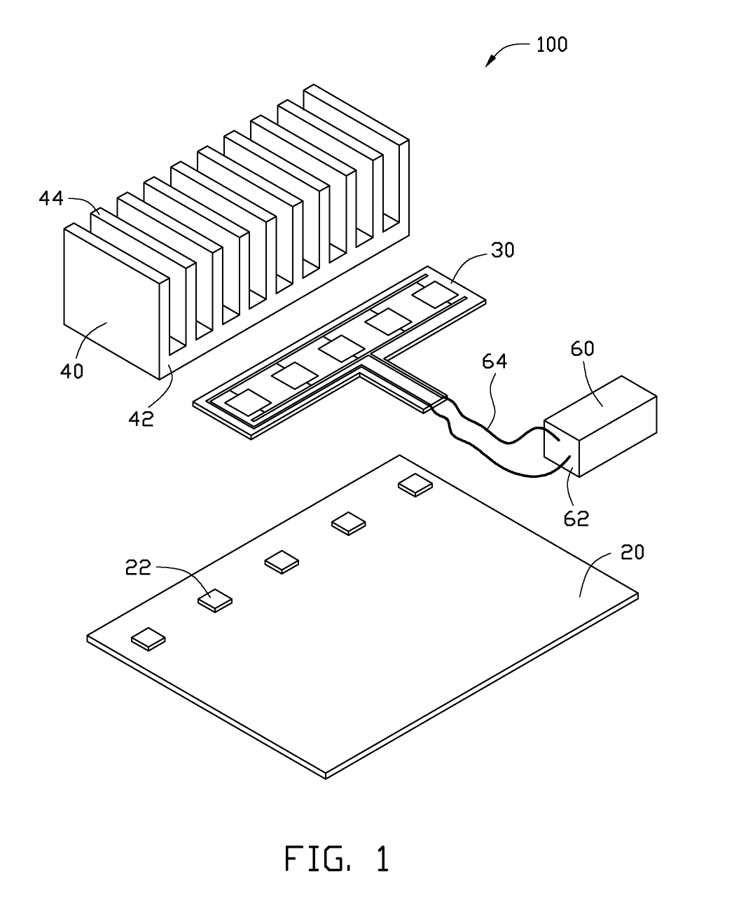

FIG. 1 shows an embodiment of a circuit board test apparatus 100, which includes a circuit board 20, an electric heating member 30, a heat sink 40, and a power supply 60. A plurality of mounting portions 22 is formed on the circuit board 20. In the embodiment, the circuit board 20 is a computer motherboard.

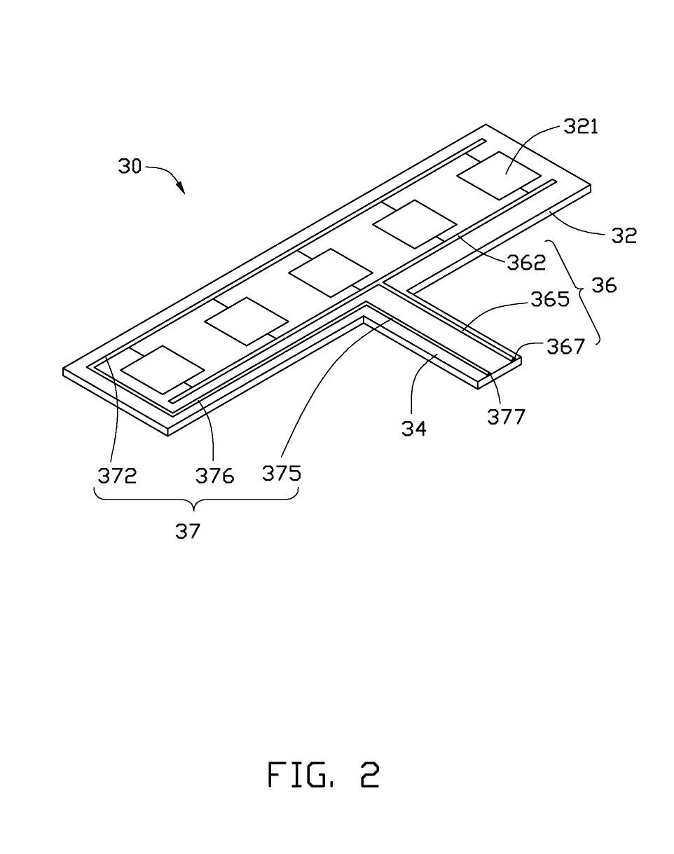

FIG. 2 shows the electric heating member 30, which is substantially T-shaped, and includes a substantially rectangular position plate 32 and a connecting plate 34 perpendicularly extending out from a middle of a first side of the position plate 32. The position plate 32 and the connecting plate 34 are made of non-conductive material. A plurality of electric heat tabs 321 is set on the position plate 32, and arrayed in a lengthwise direction of the position plate 32. A first cable 36 and a second cable 37 are arranged on the position plate 32 and the connecting plate 34. The first cable 36 includes a first conductive portion 362 arranged on the first side of the position plate 32 adjacent to the connecting plate 34, and a first extension portion 365 arranged on a first side of the connecting plate 34. The first conductive portion 362 extends along the lengthwise direction of the position plate 32. A first end of the first extension portion 365 is connected to the first conductive portion 362, and a first terminal 367 is formed on a second end of the first extension portion 365. The first terminal 367 is opposite to the first conductive portion 362. The second cable 37 includes a second conductive portion 372 arranged on a second side of the position plate 32 opposite to the first conductive portion 362, a second extension portion 375 arranged on a second side of the connecting plate 34 opposite to the first extension portion 365, and an L-shaped connecting portion 376 connected between the second conductive portion 372 and the second extension portion 375. A second terminal 377 is formed on a distal end of the second extension portion 375. The first conductive portion 362 is parallel to the second conductive portion 372. The electric heat tabs 321 are located between the first conductive portion 362 and the second conductive portion 372, and connected between the first conductive portion 362 and the second conductive portion 372 in parallel.

The heat sink 40 includes a base 42 and a plurality of fins 44 protruding up from the base 42.

The power supply 60 includes a main body 62 and two cables 64 electrically connected to the main body 62. In one embodiment, the power supply 60 is a 12 volt (V) power supply for providing 12V to a host computer.

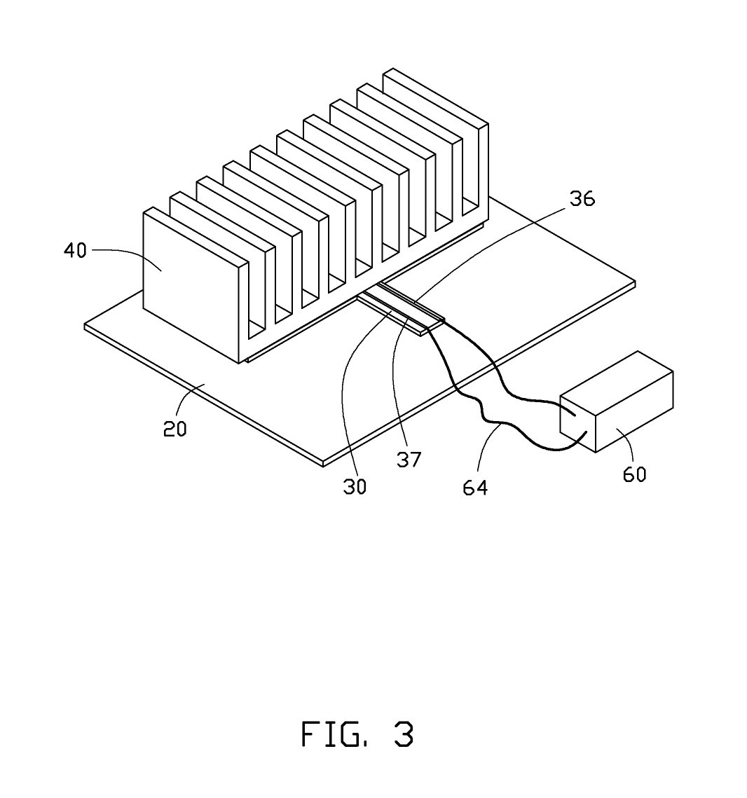

FIG. 3 shows that in use, the position plate 32 is mounted on the circuit board 20, to allow the electric heat tabs 321 to align with the mounting portions 22. The base 42 of the heat sink 40 is mounted on the position plate 32. The cables 64 are electrically connected to the first and second terminals 367 and 377. The power supply 60 is turned on. The power supply 60 provides voltages to the electric heat tabs 321 for simulating the operation states of a plurality of electronic elements designed to be mounted on the positions where the mounting portions 22 are positioned on the computer motherboard to be tested.

The electric heating member 30 can simulate the heat states of the electronic elements of the computer motherboard through the circuit board 20. In one embodiment, the electronic elements can be a plurality of peripheral component interconnection (PCI) sockets, and a plurality of memory sockets. The circuit board test apparatus 100 can replace a sample of the computer motherboard for performing thermal characteristic tests. The circuit board test apparatus 100 is time saving and low cost.

It is to be understood, however, that even though numerous characteristics and advantages of the embodiment have been set forth in the foregoing description, together with details of the structure and function of the embodiment, the disclosure is illustrative only, and changes may be made in detail, especially in the matters of shape, size, and arrangement of parts within the principles of the present disclosure to the full extent indicated by the broad general meaning of the terms in which the appended claims are expressed.

What is claimed is:

1. An electric heating member, comprising:
a position plate;
a connecting plate extending out from a first side of the position plate;
a first cable comprising a first conductive portion arranged on the first side of the position plate along a lengthwise direction of the position plate, and a first extension portion extending to the connecting plate from the first conductive portion for being electrically coupled to a power supply;
a second cable comprising a second conductive portion arranged on a second side of the position plate opposite to the first conductive portion, and a second extension portion extending to the connecting plate from the second conductive portion for being electrically coupled to the power supply; and
a plurality of electric heat tabs set on the position plate and arrayed along the lengthwise direction of the position plate;
wherein the plurality of electric heat tabs is connected between the first conductive portion and the second conductive portion in parallel.

2. The electric heating member of claim 1, wherein the position plate is rectangular, the second cable further comprises an L-shaped connecting portion connected between the second conductive portion and the second extension portion.

3. The electric heating member of claim 1, wherein the position plate and the connecting plate are made of non-conductive material.

4. A circuit board test apparatus, comprising:
a circuit board comprising a plurality of mounting portions;
an electric heating member comprising:
a position plate mounted on the circuit board;
a connecting plate extending out from a first side of the position plate;
a first cable comprising a first conductive portion arranged on the first side of the position plate along a lengthwise direction of the position plate, and a first extension portion extending to the connecting plate from the first conductive portion;
a second cable comprising a second conductive portion arranged on a second side of the position plate opposite to the first conductive portion, and a second extension portion extending to the connecting plate from the second conductive portion; and
a plurality of electric heat tabs set on the position plate and arrayed along the lengthwise direction of the position plate, and mounted on the mounting portions of the circuit board;
a heat sink mounted on the plurality of electric heat tabs; and
a power supply electrically coupled to the first and second extension portions;
wherein the plurality of electric heat tabs is connected between the first conductive portion and the second conductive portion in parallel.

5. The circuit board test apparatus of claim 4, wherein the position plate is rectangular, the second cable further comprises an L-shaped connecting portion connected between the second conductive portion and the second extension portion.

6. The circuit board test apparatus of claim 4, wherein the position plate and the connecting plate are made of non-conductive material.
